(19) United States
(12) Patent Application Publication
(10) Pub. No.: US 2024/0385226 A1
(43) Pub. Date: Nov. 21, 2024

(54) Monitoring System and Monitoring Method of Wire Between Power Supply End and Equipment End

(71) Applicant: Jet Optoelectronics Co., Ltd., Taipei City (TW)

(72) Inventors: Yao-Sheng Liu, New Taipei City (TW); Chun-Jen Lee, New Taipei City (TW)

(21) Appl. No.: 18/511,132

(22) Filed: Nov. 16, 2023

(30) Foreign Application Priority Data
May 18, 2023 (TW) 112118441

(51) Int. Cl. G01R 19/165; G01R 31/40; G01R 31/58; H02H 3/04; H02H 3/10; H02H 3/28

(52) U.S. Cl. CPC G01R 19/16538; G01R 31/40; G01R 31/58; H02H 3/04; H02H 3/10; H02H 3/28

(57) ABSTRACT

A monitoring system and a monitoring method of a wire between a power supply end and an equipment end are disclosed. The monitoring system includes a power supply loop, a monitoring device and a warning device. The power supply loop includes a voltage source and a power wire. The monitoring device is coupled to the power supply loop. The monitoring device includes a current sensor, a voltage sensor and a controller. The current sensor detects an input current of the voltage source, and the voltage sensor detects the input voltage of the voltage source. The controller receives the input current and the input voltage to obtain a loop impedance of the power supply loop. The warning device is coupled to the controller. When the loop impedance exceeds a predetermined warning impedance, the warning device sends out a warning message.

### CROSS-REFERENCE TO RELATED APPLICATION

This application claims the benefit of Taiwan Patent Application No. 112118441, filed on May 18, 2023, in the Taiwan Intellectual Property Office, the disclosure of which is incorporated herein in its entirety by reference.

### BACKGROUND OF THE INVENTION

### 1. Field of the Invention

The present invention generally relates to a monitoring system and monitoring method of a wire between a power supply end and an equipment end, in particular to a monitoring system and monitoring method thereof for monitoring a loop impedance of a wire between a power supply end and an equipment end through a monitoring device, and avoiding damage to electric devices through warning or cutting off power.

### 2. Description of the Related Art

In the human living environment, various power-driven devices are constantly developing, whether it is consumer electronics products such as personal computers, notebook computers or smart phones, or household appliances such as refrigerators, electric cookers, microwave ovens, and even a hybrid vehicle or electric vehicle, etc., it is necessary to provide the required electric energy through a power supply device. Among the existing power supply devices, most of the power supply is powered by physical power wires, and there are usually no means to monitor the power supply status and the transmission status of the power wires, and it is also impossible to quickly evaluate the usage or wear status of the wires. When the power supply is found to have problems, it is often that the wire has been burned due to high temperature or the connected load device has been damaged due to power supply problems. Those incidents are difficult to prevent in advance at the power supply end and equipment end, and easy to cause safety concerns.

In order to understand the operating status of the power supply device, the power supply device must further include corresponding signal transmission devices, such as Bluetooth, WIFI and other wireless network communication devices, or adding additional physical wires to transmit relevant information of the power supply device. On the other hand, a corresponding receiving device must be added on the equipment end to obtain information from the power supply device, which significantly increases the manufacturing cost of the equipment. In addition, for the wires between the power supply end and the equipment end, it is difficult to instantly test and monitor whether the wires are damaged due to aging or improper power supply using the above signal transmission method. Therefore, it is difficult for the conventional technology to monitor the usage status of the power supply loop and ensure the safety of the power supply end and the equipment end.

In view of the forgoing, it is difficult to monitor the power supply status information of existing power supply devices, and the power supply quality and power supply efficiency may be easily affected due to aging of the power supply or damage to the wires during the power supply process. In this regard, the inventors of the present invention had designed a monitoring system and monitoring method for the wire between power supply end and equipment end to improve the shortcomings of the conventional technology and thereby enhance industrial implementation and utilization.

### SUMMARY OF THE INVENTION

Therefore, it is a primary objective of the present invention to provide a monitoring system and monitoring method of wire between power supply end and equipment end to improve the shortcomings of existing power supply device which is difficult to monitor the wire between the power supply end and the equipment end.

To achieve the foregoing objective, the present invention provides a monitoring system of wire between power supply end and equipment end, which comprises a power supply loop, a monitoring device and a warning device. Wherein, the power supply loop including a voltage source and a power wire, the power wire provides a power supply voltage through the voltage source. The monitoring device being coupled to the power supply loop, the monitoring device includes a current sensor, a voltage sensor and a controller, the current sensor being arranged in series between the power supply loop and the controller to detect an input current of the voltage source, the voltage sensor being arranged in parallel between the power supply loop and the controller to detect an input voltage of the voltage source, the controller receives the input current and the input voltage to obtain a loop impedance of the power supply loop. The warning device being coupled to the controller, when the loop impedance exceeds a predetermined warning impedance, the warning device sends out a warning message.

Preferably, the monitoring device may be coupled to a load device, the current sensor detects a load input current after the load device is coupled, and when the load input current falls within a warning current range, the warning device sends out the warning message.

Preferably, when the load input current exceeds the warning current range, the controller may cut off power supply of the power supply loop to the load device.

Preferably, the voltage sensor may detect a load input voltage after the load device is coupled, the controller receives the load input current and the load input voltage to obtain the loop impedance.

Preferably, when the loop impedance exceeds a predetermined cut off impedance, the controller may cut off power supply of the power supply loop to the load device.

Preferably, the controller may obtain a load power supply voltage through the loop impedance, the load input current and the load input voltage, when the load power supply voltage falls within a warning voltage range, the warning device sends out the warning message.

Preferably, when the load power supply voltage exceeds the warning voltage range, the controller may cut off power supply of the power supply loop to the load device.

To achieve the foregoing objective, the present invention further provides a monitoring method of wire between power supply end and equipment end, which is applied to a monitoring system including a power supply loop, a monitoring device and a warning device, the monitoring method comprises the following steps: setting a current sensor, a voltage sensor and a controller of the monitoring device, the current sensor being arranged in series between the power supply loop and the controller, the voltage sensor being arranged in parallel between the power supply loop and the controller; detecting an input current of a voltage source of the power supply loop by the current sensor, and detecting an input voltage of the voltage source by the voltage sensor; receiving the input current and the input voltage by the controller to obtain a loop impedance of the power supply loop; and determining whether the loop impedance exceeds a predetermined warning impedance by the controller, if yes, the warning device sends out a warning message, if no, the current sensor and the voltage sensor rerun the detection.

Preferably, the monitoring device may be coupled to a load device, the current sensor detects a load input current after the load device is coupled, the controller determines whether the load input current falls within a warning current range, if yes, the warning device sends out a warning message; if no, the current sensor rerun the detection.

Preferably, the controller may determine whether the load input current exceeds the warning current range, if yes, the controller cuts off power supply of the power supply loop to the load device, if no, the current sensor rerun the detection.

Preferably, the voltage sensor may detect a load input voltage after the load device is coupled, the controller receives the load input current and the load input voltage to obtain the loop impedance.

Preferably, the controller may determine whether the loop impedance exceeds a predetermined cut off impedance, if yes, the controller cuts off power supply of the power supply loop to the load device, if no, the current sensor and the voltage sensor rerun the detection.

Preferably, the controller may obtain a load power supply voltage through the loop impedance, the load input current and the load input voltage, the controller determine whether the load power supply voltage falls within a warning voltage range, if yes, the warning device sends out the warning message, if no, the current sensor and the voltage sensor rerun the detection.

Preferably, the controller may determine whether the load power supply voltage falls within a warning voltage range, if yes, the controller cuts off power supply of the power supply loop to the load device, if no, the current sensor and the voltage sensor rerun the detection.

The monitoring system and monitoring method of wire between power supply end and equipment end according to the present invention may have the following advantages:

(1) The monitoring system and monitoring method of wire between power supply end and equipment end may be coupled to the power supply loop through the monitoring device, and the monitoring device can detect the power supply status of the wire between the power supply end and the equipment end, and provide early warning of possible problems and perform corresponding countermeasures to improve the quality of power supply from the power supply end to the equipment end, and improve operational safety.

(2) The monitoring system and monitoring method of wire between power supply end and equipment end can monitor the power supply through the monitoring device that is set up independently or installed on the load device. Therefore no need to add additional signal collection and transmission devices at the power supply end, and thus reducing installation costs while suitable for various power supply devices, and also increasing the equipment and fields in which the device can be applied.

(3) The monitoring system and monitoring method of wire between power supply end and equipment end can monitor the connection status of the wire through the detection of current, voltage and loop impedance, to determine whether the power supply loop or connector is aged, or whether the wire is abnormal or damaged. The system and method can perform long-term continuous monitoring to improving the stability and accuracy of the monitoring system and monitoring method.

### BRIEF DESCRIPTION OF THE DRAWINGS

The detailed structure, operating principle and effects of the present invention will now be described in more details hereinafter with reference to the accompanying drawings that show various embodiments of the invention as follows.

FIG. 1 is a block diagram of the monitoring system of wire between power supply end and equipment end according to an embodiment of the present invention;

FIG. 2 is a flow chart of the monitoring method of wire between power supply end and equipment end according to an embodiment of the present invention;

FIG. 3 is a schematic view of the monitoring system of wire between power supply end and equipment end according to another embodiment of the present invention;

FIG. 4 is a flow chart of the monitoring method of wire between power supply end and equipment end according to another embodiment of the present invention; and

FIG. 5 is a flow chart of the abnormal handling process according to an embodiment of the present invention.

### DETAILED DESCRIPTION OF THE PREFERRED EMBODIMENTS

In order to facilitate the understandings of the technical features, content, advantages and effects of the present invention, the present invention is described in detail below in conjunction with the accompanying drawings and in the form of embodiments described hereinafter. The purpose of the drawings is only for illustration and auxiliary description, and does not necessarily represent the actual proportions and precise configurations after implementation of the present invention. Therefore, it should be known that the proportions and configuration relationships of the attached drawings should not be interpreted to limit the scope of the present invention in actual implementation.

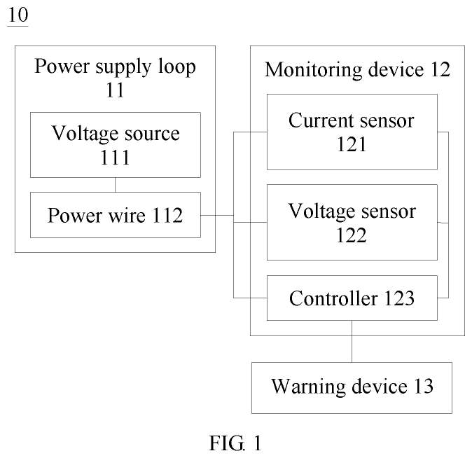

With reference to FIG. 1 for a block diagram of the monitoring system of wire between power supply end and equipment end according to an embodiment of the present invention. As shown in the figure, the monitoring system of wire between power supply end and equipment end 10 includes a power supply loop 11, a monitoring device 12 and a warning device 13. The power supply loop 11 includes a voltage source 111 and a power wire 112, and may be power supply equipment such as batteries, mains electricity, generators, wind power generation, solar power generation, etc. The power wire 112 provides power supply voltage from the voltage source 111, and provides electrical energy to electrical equipment in need. In the present embodiment, the quality of the power supply is not monitored by the signals of the power state transmitted by the power supply loop 11. Therefore, the power supply loop 11 does not need additional signal collection and transmission devices, and can be applied to various existing power supply equipment.

In order to monitor the power supply quality of the power supply equipment, the monitoring device 12 is configured to be coupled to the power supply loop 11, the monitoring device 12 includes a current sensor 121, a voltage sensor 122 and a controller 123, the current sensor 121 is arranged in series between the power supply loop 11 and the controller 123 to detect an input current of the voltage source 111, the voltage sensor 122 is arranged in parallel between the power supply loop 11 and the controller 123 to detect an input voltage of the voltage source 111, the controller 123 receives the input current and the input voltage to obtain a loop impedance of the power supply loop 11. The monitoring device 12 may be in the form of an external box or an external wire, and is coupled to the power wire 112 of the power supply loop 11 with a connector compatible with the power supply equipment. The input current of the electric energy provided by the power wire 112 can be detected by the current sensor 121, and the input voltage is detected by the voltage sensor 122. Since the monitoring device 12 is not coupled to a load device, only the input current and the input voltage are used to calculate the loop impedance of the power wire 112.

The controller 123 can be configured in the form of a chip or a circuit, be connected to the current sensor 121 and the voltage sensor 122 respectively, and receiving the input current and the input voltage. Various comparators or Micro-Control Units (MCU) with ADC functions (such as a voltage or current comparison circuit) can be included inside the controller 123, and may convert the current and voltage into numerical values to compare the numerical values. When the input current or input voltage exceeds a predetermined voltage value or current value, a warning range is exceeded and the controller 123 may send a warning signal to the warning device 13, and the warning device 13 issues a warning message. In another embodiment, the controller 123 may also include a computing device and a memory device, which calculates the loop impedance through the input current and input voltage, and compares them with the predetermined impedance value of the memory device. When the predetermined warning impedance value is exceeded, the controller 123 sends a warning signal to the warning device 13 to issue a warning message. The warning device 13 can be a signal transmitting device that transmits warning messages to the user's portable device or monitoring device through a wireless communication network. The warning device 13 can also be a display device or a light signal, which is installed on the monitoring device 12 and presents the warning message through a display screen or light signal.

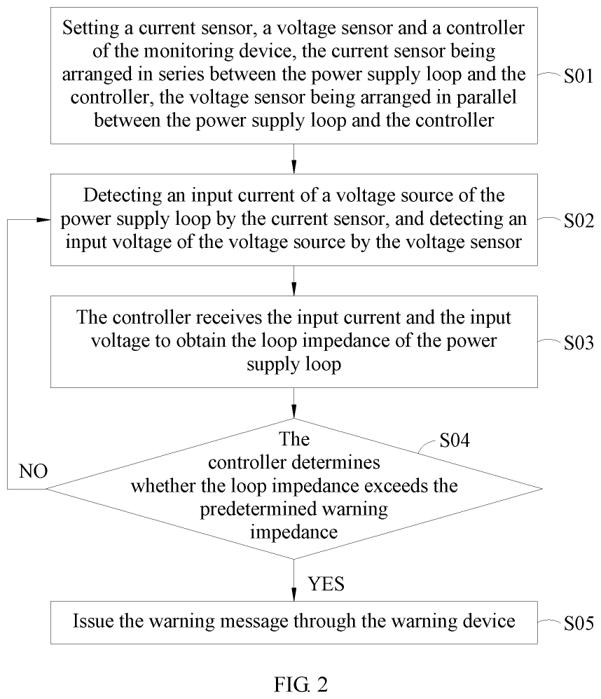

With reference to FIG. 2 for a flow chart of the monitoring method of wire between power supply end and equipment end according to an embodiment of the present invention. Also referring to FIG. 1, the monitoring method is applied to the monitoring system 10 including the power supply loop 11, the monitoring device 12 and the warning device 13. As shown in the figure, the monitoring method of wire between power supply end and equipment end includes the following steps (S01-S05):

Step S01: Setting a current sensor, a voltage sensor and a controller of the monitoring device, the current sensor being arranged in series between the power supply loop and the controller, the voltage sensor being arranged in parallel between the power supply loop and the controller. Connect the monitoring device 12 to the power supply loop 11 so that the current sensor 121, the voltage sensor 122 and the controller 123 of the monitoring device 12 are connected to the power wire 112.

Step S02: Detecting an input current of a voltage source of the power supply loop by the current sensor, and detecting an input voltage of the voltage source by the voltage sensor. After the monitoring device 12 and the power supply loop 11 are connected, the power provided from the voltage source 111 may be detected where the input current input to the monitoring device 12 is detected by the current sensor 121, and the input voltage is detected by the voltage sensor 122. The number of times and frequency of the detection can be adjusted according to the type of power supply equipment.

Step S03: The controller receives the input current and the input voltage to obtain the loop impedance of the power supply loop. Since the current sensor 121 and the voltage sensor 122 may detect the input current and the input voltage respectively, the controller which is connected to the current sensor 121 and the voltage sensor 122 may receive the input current and the input voltage, and calculate the loop impedance of the power supply loop 11 through a computing device, that is, the loop impedance of the power wire 112 between the voltage source 111 and the monitoring device 12, and the use status of the power wire 112 can be monitored through the loop impedance.

Step S04: The controller determines whether the loop impedance exceeds the predetermined warning impedance, if yes, proceed to step S05; if no, then return to step S02, and the current sensor and voltage sensor will rerun the detection. In the controller 123, whether an abnormal condition occurs is determined by comparing the loop impedance with the predetermined warning impedance. When the loop impedance exceeds the predetermined warning impedance, it indicates that the power supply loop 11 may be aging at the voltage source 111 or the power wire 112 may be damaged. In an abnormal state, the controller 123 may send a warning signal to the warning device 13 to issue a warning message. If the loop impedance does not exceed the predetermined warning impedance, the current sensor 121 and the voltage sensor 122 of the monitoring device 12 rerun the detection and continue to monitor the power supply loop 11.

Step S05: Issue the warning message through the warning device. The warning device 13 can be a signal transmitting device that transmits warning messages to the user's portable device or monitoring device through a wireless communication network. The warning device 13 can be a display device or a light signal, which is installed on the monitoring device 12 and presents the warning messages through a display or light signal.

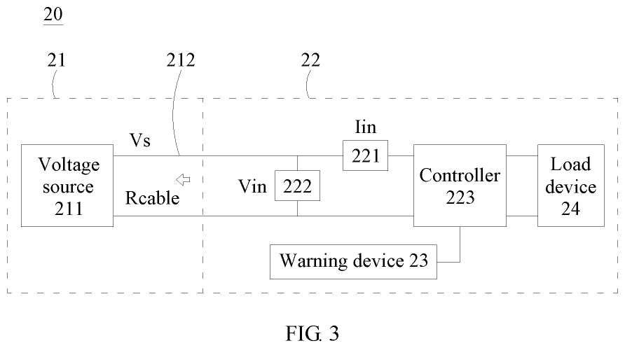

With reference to FIG. 3 for a schematic view of the monitoring system of wire between power supply end and equipment end according to another embodiment of the present invention. As shown in the figure, the monitoring system of the wire between the power supply end and the equipment end 20 includes a power supply loop 21, a monitoring device 22 and a warning device 23. The power supply loop 21 includes a voltage source 211 and a power wire 212, and may be power supply equipment such as batteries, mains electricity, generators, wind power generation, solar power generation, etc. The power wire 212 provides power supply voltage Vs from the voltage source 211, and provides electrical energy to electrical equipment in need. The monitoring device 22 is coupled to the power supply loop 21, the monitoring device 22 includes a current sensor 221, a voltage sensor 222 and a controller 223, the current sensor 221 is arranged in series between the power supply loop 21 and the controller 223 to detect an input current Iin of the voltage source 211, the voltage sensor 222 is arranged in parallel between the power supply loop 21 and the controller 223 to detect an input voltage Vin of the voltage source 211, the controller 223 receives the input current Iin and the input voltage Vin to obtain a loop impedance Rcable of the power supply loop 11.

The warning device 23 is coupled to the controller 223, and transmits a warning message to the user's portable device or monitoring device through a signal transmission device, or presents a warning message through a display device or a light signal. Different from the previous embodiments, the monitoring device 22 is coupled to the load device 24, and the load device 24 is an electric device requiring power supply, such as a notebook computer, a desktop computer, a tablet computer, a smart phone and other consumer electronic products, or home appliances such as electric cookers, electric heaters, refrigerators, ovens, microwave ovens, etc., or electric devices such as electric locomotives and electric cars. These electrical devices all need to be supplied with electrical energy through the power supply loop 21 to provide charging or electrical energy-driven operations. The monitoring device 22 can be in the form of an external box or an external circuit, and is coupled between the power wire 212 of the power supply loop 21 and the load device 24 with a joint that conforms to the power supply equipment and the electrical equipment, or the monitoring device 22 can be in the form of a circuit or a chip installed in the load device 24 and coupled to the power wire 212 of the power supply loop 21 through built-in connectors of the load device 24.

When the monitoring device 22 is coupled to the load device 24, the input current Iin originally detected by the current sensor 221 is transformed into the load input current Iin(L) detected after the load device 24 is coupled, and the controller 223 can monitor the load input current Iin(L). When the load input current Iin(L) is within the warning current range, the warning device 23 will send out a warning message. When the load input current Iin(L) exceeds the warning current range, the controller 223 can cut off the power supply from the power supply loop 21 to the load device 24.

For example, the input of the power supply end is the 12V power supply of the car, and the equipment end is the car charger. After the power is input and through voltage and current sensing, the DC/DC converter converts the 12V power supply to the voltage required by the charged device (such as 20V and 5A output), and provide mobile phones, laptops, tablets, scooters, and such for charging through the Type C interface at the output end. The maximum charging power can be 100 W. Taking such a car charger as an example, the quality specification stipulates that the normal current range is 0 to 10 amps (0 A≤in(L)≤10 A), and the warning current range is between 10 and 12 amps (10 A<Iin(L)<12 A), the power cut-off range is over 12 amps (Iin(L)>12 A), when detected that the load input current Iin(L) exceeds 12 amps, the microprocessor in the car charger outputs a control command to stop the DC/DC converter, and cut off the power switch to stop charging, and when the current is in the range of 10 to 12 amps, a warning signal is issued by the warning device 23, such as a LED light signal for warning or stop signals controlled by a microprocessor installed in the car charger.

When the monitoring device 22 is coupled to the load device 24, the voltage sensor 222 which originally detects the input voltage Vin is changed to detect the load input voltage Vin(L) after the load device 24 is coupled, and the controller 223 receive the load input current Iin(L) and the load input voltage Vin(L) to obtain the loop impedance Rcable. The calculation formula is as shown in the following equation (1).

Loop impedance Rcable=(Vin−Vin(L))/(Iin(L)−Iin) (1)

The controller 223 compares the loop impedance Rcable with a predetermined impedance value, and when the predetermined warning impedance value is exceeded, the controller 223 sends a warning signal to the warning device 23 to issue a warning message; and when the loop impedance Rcable exceeds the predetermined cut-off impedance, the controller 223 can cut off the power supply from the power supply loop 21 to the load device 24. For example, the quality inspection specification stipulates that the loop impedance Rcable should be less than 0.03 ohm, and if exceeded, a warning message will be issued. In another embodiment, the predetermined cut-off impedance may also be omitted, for example, when the impedance of the car charger in the foregoing embodiment is relatively large, the charging power of 100 W cannot be reached, and thus the charging power is changed to 15 W, therefore by determining whether the charging power is within the 100 W working range can be the trigger condition for issuing a warning.

When the monitoring device 22 is coupled to the load device 24, the current sensor 221 detects the load input current Iin(L) after the load device 24 is coupled, and the voltage sensor 222 detects the load input voltage Vin(L) after the load device 24 is coupled, and the controller 223 receives the load input current Iin(L) and the load input voltage Vin(L) to obtain the loop impedance Rcable. The controller 223 may further calculate the load power supply voltage Vs(L), and the calculation formula is as shown in the following equation (2).

Load power supply voltage Vs(L)=Vin(L)+Rcable*Iin(L) (2)

The controller 223 can monitor the load power supply voltage Vs(L), when the load power supply voltage Vs(L) is within the warning voltage range, the warning device 23 issues a warning message; and when the load power supply voltage Vs(L) exceeds the warning voltage range, the controller 223 can cut off the power supply from the power supply loop 21 to the load device 24. Also taking the aforementioned car charger as an example, the quality inspection specification stipulates that the normal voltage range is 9 to 16 volts (9V≤Vs(L)≤16V), and the warning voltage range is between 8.5 and 9 volts (8.5V≤Vs(L)<9V) or between 16 and 16.5 volts (16<Vs(L)≤16.5V), the cut-off power supply range is lower than 8.5 volts or more than 16.5 volts (Vs(L)<8.5V or Vs(L)>16.5V), when detected that the load power supply voltage Vs(L) is lower than 8.5 volts or exceeds 16.5 volts, the microprocessor in the car charger outputs a control command to stop the DC/DC converter, and cut off the power switch to stop the charging, and when detected between 8.5 to 9 volts or between 16 to 16.5 volts, a warning signal is sent by the warning device 23, such as a LED light signal for warning or stop signals controlled by a microprocessor installed in the car charger. The LED lights can be set in multiple colors, and different colors of lights can be used to distinguish warning or stop signals.

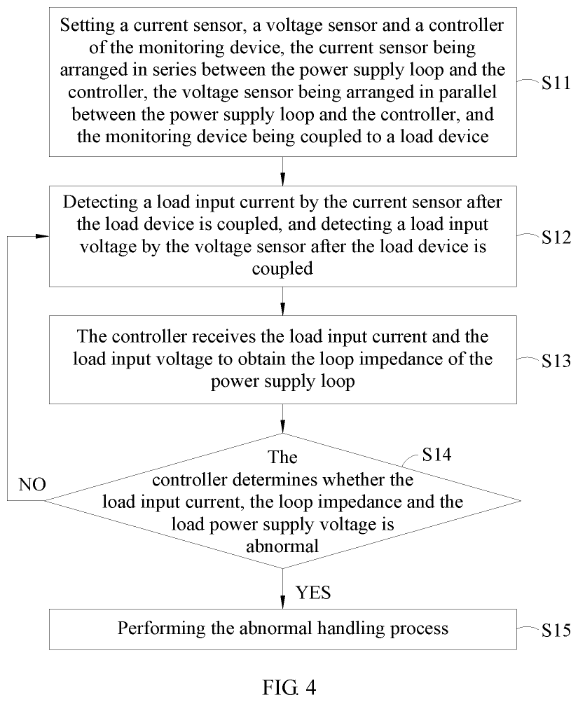

With reference to FIG. 4 for a flow chart of the monitoring method of wire between power supply end and equipment end according to another embodiment of the present invention. Also referring to FIG. 3, the monitoring method is applied to the monitoring system 20 including the power supply loop 21, the monitoring device 22, the warning device 23 and the load device 24. As shown in the figure, the monitoring method of wire between power supply end and equipment end includes the following steps (S11-S15):

Step S11: Setting a current sensor, a voltage sensor and a controller of the monitoring device, the current sensor being arranged in series between the power supply loop and the controller, the voltage sensor being arranged in parallel between the power supply loop and the controller, and the monitoring device being coupled to a load device. Connect the monitoring device 22 to the power supply loop 21 so that the current sensor 221, the voltage sensor 222 and the controller 223 of the monitoring device 22 are connected to the power wire 212. The load device 24 is coupled to the controller 223 of the monitoring device 22. The monitoring device 22 can be in the form of an external box or an external circuit, and is coupled between the power wire 212 of the power supply loop 21 and the load device 24 with a joint that conforms to the power supply equipment and the electrical equipment, or the monitoring device 22 can be in the form of a circuit or a chip installed in the load device 24 and coupled to the power wire 212 of the power supply loop 21 through built-in connectors of the load device 24.

The load device 24 is an electric device requiring power supply, such as a notebook computer, a desktop computer, a tablet computer, a smart phone and other consumer electronic products, or home appliances such as electric cookers, electric heaters, refrigerators, ovens, microwave ovens, etc., or electric devices such as electric locomotives and electric cars. These electrical devices all need to be supplied with electrical energy through the power supply loop 21 to provide charging or electrical energy-driven operations.

Step S12: Detecting a load input current by the current sensor after the load device is coupled, and detecting a load input voltage by the voltage sensor after the load device is coupled. After the monitoring device 22 and the power supply loop 21 are connected, and coupled to the load device 24, the electric energy provided by the voltage source 211 can be detected by the current sensor 221 in terms of load input current Iin(L) after the load device 24 is coupled, and the voltage sensor 222 can be used to detect the load input voltage Vin(L) after the load device 24 is coupled. The number of times and frequency of detection can be adjusted according to the type of power supply equipment and the electrical equipment. For example, if the electrical equipment is a device that is continuously powered on, such as a refrigerator, the power supply loop 21 is continuously powered and can be set at a fixed interval for continuous monitoring. If the electrical equipment is turned on for a period of time and turned off or powered off thereafter, such as an electric oven, it can be set to perform a predetermined number of detections after being turned on. If no abnormality occurred, the detection will be stopped and the monitoring will be restarted the next time it is turned on again.

Step S13: The controller receives the load input current and the load input voltage to obtain the loop impedance of the power supply loop. When the monitoring device 22 is coupled to the load device 24, the input current Iin originally detected by the current sensor 221 is changed to the load input current Iin(L) detected after being coupled to the load device 24, and the input voltage Vin originally detected by the voltage sensor 222 is changed to the load input voltage Vin(L) detected after being coupled to the load device 24. The controller 223 can calculate the loop impedance Rcable of the power supply loop 21 through a computing device. The calculation formula is shown in the previous equation (1). The usage status of the power supply loop 21 is monitored through the loop impedance Rcable.

Step S14: The controller determines whether the load input current, the loop impedance and the load power supply voltage is abnormal, if yes, proceed to step S15; if no, then return to step S12, and the current sensor and voltage sensor will rerun the detection. In the controller 223, whether an abnormal condition is occurred is determined by comparing the load input current Iin(L), the loop impedance Rcable, and the load power supply voltage Vs(L) with the predetermined set values.

Regarding the load input current Iin(L), whether the load input current Iin(L) is within the warning current range or exceeds the warning current range is determined, for example, the normal current range is set to be 0 to 10 amps (0 A≤Iin(L)≤10 A), the warning current range is between 10 and 12 amps (10 A<Iin(L)<12 A), and the cut-off power range is more than 12 amps (Iin(L)>12 A), when the load input current Iin(L) is detected to exceeds 10 amps, it is determined that there may be a problem with the load device 24, such as a short circuit or a leakage, and enters the abnormal handling process of step S15; if detected below 10 amps, the current sensor 221 and the voltage sensor 222 rerun the detection, and continuously monitor the power supply loop 21.

Regarding the loop impedance Rcable, whether the loop impedance Rcable is within the predetermined warning impedance range or exceed the predetermined warning impedance value is determined, for example, the loop impedance Rcable should be less than 0.03 ohm, if the loop impedance Rcable exceeds 0.03 ohm, it may indicate that the power supply loop 21 is aging or the power wire 212 is abnormal, and enters the abnormal handling process of step S15; if it does not exceed 0.03 ohm, then return to step S12, the current sensor 221 and the voltage sensor 222 rerun the detection, and continuously monitor the power supply loop 21.

Regarding the load power supply voltage Vs(L), whether the load power supply voltage Vs(L) is within the warning voltage range or exceeds the warning voltage range is determined, such as setting the normal voltage range as 9 to 16 volts (9V≤Vs(L)≤16V), the warning voltage range is between 8.5 and 9 volts (8.5V≤Vs(L)<9V) or between 16 and 16.5 volts (16<Vs(L)≤16.5V), the cut-off power range is lower than 8.5 volts or higher than 16.5 volts (Vs(L)<8.5V or Vs(L)>16.5V), when detected that the load power supply voltage Vs(L) is lower than 9 volts or higher than 16 volts, it is possible to determine if the power supply voltage is too high or the power supply loop is aging (too low), and enters the abnormal handling process of step S15; if detected between 9 and 16 volts, then return to step S12, the current sensor 221 and the voltage sensor 222 rerun the detection, and continuously monitor the power supply loop 21.

Step S15: Performing the abnormal handling process. The abnormal handling process includes cutting off the power supply from the power supply loop 21 to the load device 24 or transmitting a warning signal through the warning device 23. The controller 223 can determine whether to send a warning message or directly cut off the power supply, by comparing the load input current Iin(L), the loop impedance Rcable and the load power supply voltage Vs(L) with the predetermined warning range or predetermined cut-off values. The detailed abnormal handling process will be further explained in the following embodiment.

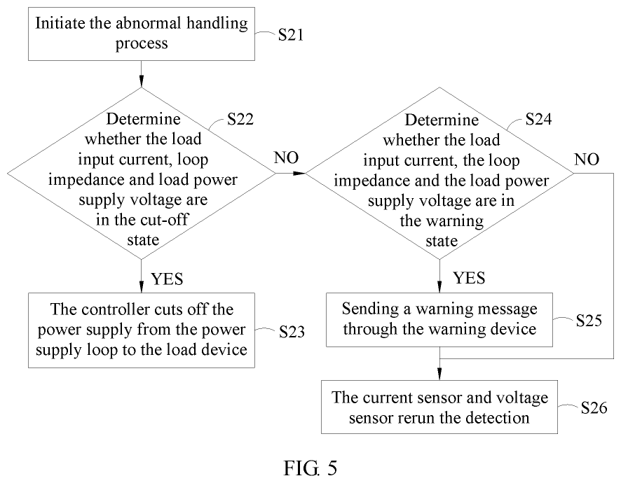

With reference to FIG. 5 for a flow chart of the abnormal handling process according to an embodiment of the present invention. Also referring to FIGS. 3 and 4, the monitoring method is applied to the monitoring system 20 including the power supply loop 21, the monitoring device 22, the warning device 23 and the load device 24. As shown in the figure, the abnormal handling process includes the following steps (S21-S28):

Step S21: Initiate the abnormal handling process. As described in the previous embodiment, the controller 223 can determine whether the load input current Iin(L), the loop impedance Rcable and the load power supply voltage Vs(L) are within the predetermined warning range or exceed the predetermined warning range respectively. When the value exceeds the predetermined normal range, the abnormal handling process is initiated.

Step S22: Determine whether the load input current, loop impedance and load power supply voltage are in the cut-off state, if yes, proceed to step S23; if no, then proceed to step S24. The controller 223 first determines whether load input current Iin(L), the loop impedance Rcable and the load power supply voltage Vs(L) meet the condition for cutting off the power supply, that is, whether the load input current Iin(L) exceeds the warning current range, whether the loop impedance exceeds the predetermined cut-off impedance or whether the load power supply voltage Vs(L) exceeds the warning voltage range. If one of the above situations occurs, proceed to step S23 to directly cut off the power supply of the power supply loop 21 to the load device 24. Whether a cut-off state is reached is determined first because when the detected value exceeds the warning range, usually the power supply loop 21 or the load device 24 is already in a certain dangerous state, such as wire damage, wire temperature being too high, or the battery has aged to a critical state, etc. In that case, the abnormal handling process is programed to immediately cut off the power supply to avoid more serious accidents such as fire or leakage. On the other hand, if the load input current Iin(L), the loop impedance Rcable and the load power supply voltage Vs(L) do not exceed the predetermined warning range, proceed to step S24 to determine whether a warning message needs to be issued.

Step S23: The controller cuts off the power supply from the power supply loop to the load device. After detecting that the load input current Iin(L), the loop impedance Rcable and the load power supply voltage Vs(L) reach the condition for cutting off the power supply, the controller 223 directly cuts off the power supply to the load device 24 from the power supply loop 21, which can be performed by disconnecting the load device 24 through a switch, or physically disconnect the wires to avoid damaging the power supply loop 21 or the load device 24 due to continuous power supply.

Step S24: Determine whether the load input current, the loop impedance and the load power supply voltage are in the warning state, if yes, proceed to step S25; if no, proceed to step S26. When it is determined that the load input current Iin(L), the loop impedance Rcable and the load power supply voltage Vs(L) have not reached the condition for cutting off the power supply, further determine whether the load input current Iin(L), the loop impedance Rcable and the load power supply voltage Vs(L) are within the predetermined warning range. As described in the previous embodiment, when the load input current Iin(L) is within the warning current range, when the loop impedance Rcable exceeds the predetermined warning impedance value, or when the load power supply voltage Vs(L) is within the warning voltage range, it indicates that there may be a problem with the power supply loop 21 or the load device 24. Therefore, proceed to step S25, and a warning message is sent through the warning device 23. On the other hand, if the load input current Iin(L), the loop impedance Rcable and the load power supply voltage Vs(L) are not within the warning range, it is viewed to have returned to the normal state and proceed to step S26, the current sensor 221 and the voltage The sensor 222 rerun the detection and continues to monitor the power supply loop 21.

In another embodiment, the controller 223 can determine whether a warning needs to be issued by determining the trends of the load input current Iin(L), the loop impedance Rcable and the load power supply voltage Vs(L), such as detecting the values for a number of periods, and determine whether the numerical curve of the detected value deviates or whether the numerical variation continues to increase. When reaching a predetermined level, it is determined that the power supply loop 21 may have a continuing aging trend, and then a warning message is sent through the warning device 23.

Step S25: Sending a warning message through the warning device. The warning device 23 may be a signal transmitting device that transmits warning messages to the user's portable device or monitoring device through a wireless communication network. The warning device 23 can also be a display device or a light signal, which may be installed on the monitoring device 22 and presents the warning messages through a display or light signal.

Step S26: The current sensor and voltage sensor rerun the detection. When it is determined that the load input current Iin(L), the loop impedance Rcable and the load power supply voltage Vs(L) return back to the normal state, the controller 223 will rerun the detection again through the current sensor 221 and the voltage sensor 222, and continuously monitor the power supply loop 21.

The above descriptions are merely illustrative, but not restrictive. Any equivalent modifications or changes made without departing from the spirit and scope of the present invention shall be included in the appended scope of the present application.

What is claimed is:

1. A monitoring system of wire between power supply end and equipment end, comprising:
a power supply loop including a voltage source and a power wire, the power wire provides a power supply voltage through the voltage source;
a monitoring device coupled to the power supply loop, the monitoring device includes a current sensor, a voltage sensor and a controller, the current sensor being arranged in series between the power supply loop and the controller to detect an input current of the voltage source, the voltage sensor being arranged in parallel between the power supply loop and the controller to detect an input voltage of the voltage source, the controller receives the input current and the input voltage to obtain a loop impedance of the power supply loop; and
a warning device coupled to the controller, when the loop impedance exceeds a predetermined warning impedance, the warning device sends out a warning message.

2. The monitoring system of wire between power supply end and equipment end of claim 1, wherein the monitoring device is coupled to a load device, the current sensor detects a load input current after the load device is coupled, and when the load input current falls within a warning current range, the warning device sends out the warning message.

3. The monitoring system of wire between power supply end and equipment end of claim 2, wherein when the load input current exceeds the warning current range, the controller cuts off power supply of the power supply loop to the load device.

4. The monitoring system of wire between power supply end and equipment end of claim 2, wherein the voltage sensor detects a load input voltage after the load device is coupled, and the controller receives the load input current and the load input voltage to obtain the loop impedance.

5. The monitoring system of wire between power supply end and equipment end of claim 4, wherein when the loop impedance exceeds a predetermined cut off impedance, the controller cuts off power supply of the power supply loop to the load device.

6. The monitoring system of wire between power supply end and equipment end of claim 4, wherein the controller obtains a load power supply voltage through the loop impedance, the load input current and the load input voltage, when the load power supply voltage falls within a warning voltage range, the warning device sends out the warning message.

7. The monitoring system of wire between power supply end and equipment end of claim 6, wherein when the load power supply voltage exceeds the warning voltage range, the controller cuts off power supply of the power supply loop to the load device.

8. A monitoring method of wire between power supply end and equipment end, which is applied to a monitoring system including a power supply loop, a monitoring device and a warning device, the monitoring method comprises the following steps:
setting a current sensor, a voltage sensor and a controller of the monitoring device, the current sensor being arranged in series between the power supply loop and the controller, the voltage sensor being arranged in parallel between the power supply loop and the controller;
detecting an input current of a voltage source of the power supply loop by the current sensor, and detecting an input voltage of the voltage source by the voltage sensor;
receiving the input current and the input voltage by the controller to obtain a loop impedance of the power supply loop; and
determining whether the loop impedance exceeds a predetermined warning impedance by the controller, if yes, the warning device sends out a warning message, if no, the current sensor and the voltage sensor rerun the detection.

9. The monitoring method of wire between power supply end and equipment end of claim 8, wherein the monitoring device is coupled to a load device, the current sensor detects a load input current after the load device is coupled, the controller determines whether the load input current falls within a warning current range, if yes, the warning device sends out a warning message; if no, the current sensor rerun the detection.

10. The monitoring method of wire between power supply end and equipment end of claim 9, wherein the controller determines whether the load input current exceeds the warning current range, if yes, the controller cuts off power supply of the power supply loop to the load device, if no, the current sensor rerun the detection.

11. The monitoring method of wire between power supply end and equipment end of claim 9, wherein the voltage sensor detects a load input voltage after the load device is coupled, the controller receives the load input current and the load input voltage to obtain the loop impedance.

12. The monitoring method of wire between power supply end and equipment end of claim 11, wherein the controller determines whether the loop impedance exceeds a predetermined cut off impedance, if yes, the controller cuts off power supply of the power supply loop to the load device, if no, the current sensor and the voltage sensor rerun the detection.

13. The monitoring method of wire between power supply end and equipment end of claim 11, wherein the controller obtains a load power supply voltage through the loop impedance, the load input current and the load input voltage, the controller determine whether the load power supply voltage falls within a warning voltage range, if yes, the warning device sends out the warning message, if no, the current sensor and the voltage sensor rerun the detection.

14. The monitoring method of wire between power supply end and equipment end of claim 13, wherein the controller determines whether the load power supply voltage falls within a warning voltage range, if yes, the controller cuts off power supply of the power supply loop to the load device, if no, the current sensor and the voltage sensor rerun the detection.
